(19) United States
(12) Patent Application Publication
(10) Pub. No.: US 2013/0122706 A1
(43) Pub. Date: May 16, 2013

(54) METHOD OF MANUFACTURING SEMICONDUCTOR DEVICE

(71) Applicants: Hisashi OKUCHI, Yokohama-shi (JP); Hidekazu Hayashi, Yokohama-shi (JP); Kentaro Shimayama, Yokohama-shi (JP); Hiroshi Tomita, Yokohama-shi (JP)

(72) Inventors: Hisashi OKUCHI, Yokohama-shi (JP); Hidekazu Hayashi, Yokohama-shi (JP); Kentaro Shimayama, Yokohama-shi (JP); Hiroshi Tomita, Yokohama-shi (JP)

(21) Appl. No.: 13/428,681

(22) Filed: Mar. 23, 2012

(30) Foreign Application Priority Data
Nov. 14, 2011 (JP) 2011-248961

(51) Int. Cl. H01L 21/306

(52) U.S. Cl. 438/694; 257/E21.215

(57) ABSTRACT

According to one embodiment, a method of manufacturing of a semiconductor device is provided. In the method, a front surface of a semiconductor substrate and a front surface of a support substrate are bonded to each other by an adhesive. A part of a circumferential part of the support substrate is subjected to water-repellent treatment to thereby form a water-repellent area on the part of the circumferential part in such a manner that the water-repellent area and an end face of the adhesive are in contact with each other. The semiconductor substrate is removed from a rear surface side by wet etching.

### CROSS-REFERENCE TO RELATED APPLICATIONS

This application is based upon and claims the benefit of priority from prior Japanese Patent Application No. 2011-248961, filed Nov. 14, 2011, the entire contents of which are incorporated herein by reference.

### FIELD

Embodiments described herein relate generally to a method of manufacturing a semiconductor device.

### BACKGROUND

In recent years, in a memory device such as a DRAM and other memory devices, a chip laminating technique using the through silicon via (TSV) technique is examined.

### BRIEF DESCRIPTION OF THE DRAWINGS

FIG. 1 is a view showing a manufacturing flow of a semiconductor device according to this embodiment.

FIGS. 2, 3, 4, 5 and 6 are cross-sectional views showing a preliminary process of TSV formation in the semiconductor device according to this embodiment.

FIGS. 7, 8 and 9 are enlarged views showing examples of a water-repellent area in FIG. 5.

### DETAILED DESCRIPTION

In general, according to one embodiment, there is provided a manufacturing method of a semiconductor device. In the method of manufacturing a semiconductor device, a front surface of a semiconductor substrate, and front surface of a support substrate are bonded to each other by an adhesive. A part of a circumferential part of the support substrate is subjected to water-repellent treatment to thereby form a water-repellent area on the part of the circumferential part in such a manner that the water-repellent area and an end face of the adhesive are in contact with each other. The semiconductor substrate is removed from a rear surface side by wet etching.

Formation of the TSV is carried out in the following manner. First, a device wafer (first device wafer) on which a circuit and the like are arranged on the front surface side is thinned from the rear surface side. At this time, the front surface side of the device wafer is bonded to the support substrate. Further, the device wafer is thinned to a desired thickness and, thereafter a through via is formed. Thereafter, a rear bump to be connected to the through via is formed, and another device wafer (second device wafer) is laminated on the first device wafer. At this time, a front bump formed on the front surface of the second device wafer, and the rear bump of the first device wafer are connected to each other to thereby carry out chip lamination.

In the film-thinning technique of the device wafer (Si wafer) constituting the intermediate process before lamination, back-side grinding, and wet etching using an etching solution are carried out.

When the wet etching is employed, it is necessary to etch only the to-be-etched surface (rear surface) of the device wafer, on which the device wafer is exposed. Accordingly, the wet etching is carried out in the spin system in which a single wafer spin etching apparatus is used. In the single wafer spin etching apparatus, the etching solution is discharged onto the surface to be etched while the device wafer is being rotated at a high rotational speed. In this case, there are two methods; one is a method in which the etching solution is discharged from a fixed nozzle, and the other is a method in which the etching solution is discharged while discharge nozzles are being scanned, and each of the methods is selected on the basis of the etching surface uniformity characteristics. Further, by rotating the device wafer at a high rotational speed, the etching solution etches the device wafer from the central part of the device wafer to the outer circumferential part thereof. After that, the etching solution is discharged to the outside of the device wafer by the centrifugal force obtained by the high-speed rotation, and is then collected.

When the device wafer is processed by using the single wafer spin etching apparatus, the etching solution advances from the outer circumferential part of the device wafer to the support substrate side depending on the wettability (hydrophilicity) between the etching solution and underlying material with which the etching solution is in contact at the outer circumferential part of the device wafer. Thereby, there is the possibility of the support substrate constituted of glass or the like, and protective film or the like formed on the support substrate being etched.

When this local etching proceeds, a contamination risk originating from the support substrate becomes a problem. For example, contamination of the device wafer resulting from the impurities contained in the support substrate or secondary contamination of a device wafer to be subsequently processed occurs. Further, the shape of the support substrate changes, whereby the number of times of repetitive use of the support substrate decreases.

As a method of preventing the etching solution from advancing from the device wafer side to the support substrate as described above, there is a method of improving the centrifugal force by increasing the rotational speed at the time of etching. Thereby, it is possible to prevent the etching solution from advancing to the support substrate.

However, when the rotational speed of the device wafer is increased, the etching characteristics of the device wafer are deteriorated. More specifically, when the rotational speed is increased to, for example, 1000 rpm or more, the etching rate of the outer peripheral side of the device wafer becomes larger, and the uniformity in film-thickness is deteriorated. As described above, from the viewpoint of keeping the etching characteristics, a method of preventing the etching solution from advancing to the support substrate other than by the method of excessively increasing the rotational speed is required.

This embodiment will be described below with reference to the drawings. In the drawings, identical parts are denoted by identical reference symbols. Further, a duplicate description will be given as the need arises.

### Embodiment

This embodiment is an example in which in the film-thinning process of the semiconductor substrate (device wafer) to be carried out by the wet etching of the spin system, the etching solution is prevented from advancing to the support substrate by subjecting the circumferential part of the support substrate supporting the semiconductor substrate to water-repellent treatment.

It should be noted that in the following, although a description will be given by taking a method of manufacturing a semiconductor device including a chip lamination process to be carried out by using the TSV technique as an example, this embodiment can generally be applied to manufacturing methods of a semiconductor device each including a spin-system wet etching process to which a to-be-processed substrate is subjected in a state where the to-be-processed substrate and support substrate are bonded to each other.

### [Manufacturing Flow of Semiconductor Device]

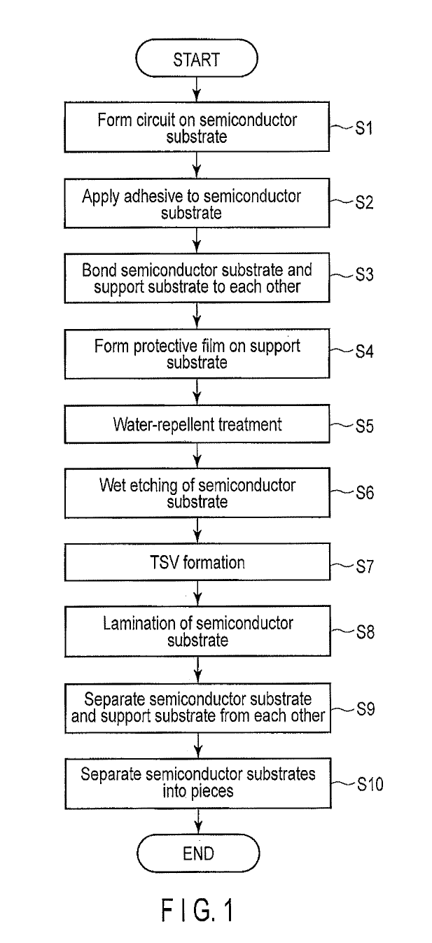

First, a manufacturing flow of the semiconductor device according to this embodiment will be described below by using FIG. 1.

FIG. 1 is a view showing the manufacturing flow of the semiconductor device according to this embodiment.

As shown in FIG. 1, first, in step S1, a circuit 13 is formed on a surface of a semiconductor substrate 10. Next, in step S2, an adhesive 15 is applied to the front surface side of the semiconductor substrate 10. Next, in step S3, the front surface of the semiconductor substrate 10, and front surface of a support substrate 20 are bonded to each other through the adhesive 15. Next, in step S4, a protective film 21 is formed on the support substrate 20. Next, in step S5, a circumferential part of the support substrate 20 is subjected to water-repellent treatment. Thereafter, in step S6, the semiconductor substrate 10 is processed from the rear surface side by the spin-system wet etching, thereby thinning the semiconductor substrate 10. Details of the processes of steps S1 to S6 will be described later.

Next, in step S7, a TSV is formed in the semiconductor substrate 10. More specifically, a hole penetrating the semiconductor substrate 10 is formed from the rear surface side of the semiconductor substrate 10 by, for example, lithography and reactive ion etching (RIE). Thereafter, a conductive material is formed to fill the hole therewith, thereby electrically connecting the front surface side of the semiconductor substrate 10, and rear surface side thereof to each other. It should be noted that the conductive material may not be filled into the hole, but may be formed on the inner surface of the hole to thereby electrically connect the front surface side of the semiconductor substrate 10, and rear surface side thereof to each other. Thereafter, a bump to be connected to the TSV is formed on the rear surface side of the semiconductor substrate 10.

Next, in step S8, another semiconductor substrate (second semiconductor substrate) on which a circuit is formed is laminated on the rear surface side of the semiconductor substrate 10 (first semiconductor substrate). Thereafter, likewise, a TSV is formed in the second semiconductor substrate, and other semiconductor substrates on each of which a circuit is formed are laminated in sequence on the second semiconductor substrate.

Next, in step S9, the semiconductor substrate 10, and support substrate 20 are separated from each other. Thereafter, in step S10, the semiconductor substrate 10, and the plurality of laminated semiconductor substrates are separated into pieces along a dicing line, thereby forming laminated semiconductor chips.

It should be noted that the process (step S10) of separating the semiconductor substrate 10 into pieces may be carried out before the lamination process (step S8) of the second semiconductor substrate. More specifically, after the TSV is formed in the semiconductor substrate 10 (step S7), the semiconductor substrate 10 is separated into pieces along the dicing line, and the first semiconductor chips are formed. Thereafter, a second semiconductor chip formed by a separate process is laminated on the rear surface side of each first semiconductor chip. Further, the process (step S9) of separating the semiconductor substrate 10, and support substrate 20 from each other may be carried out before or after the process of separating the semiconductor substrate 10 into pieces.

### [Preliminary Process of TSV Formation]

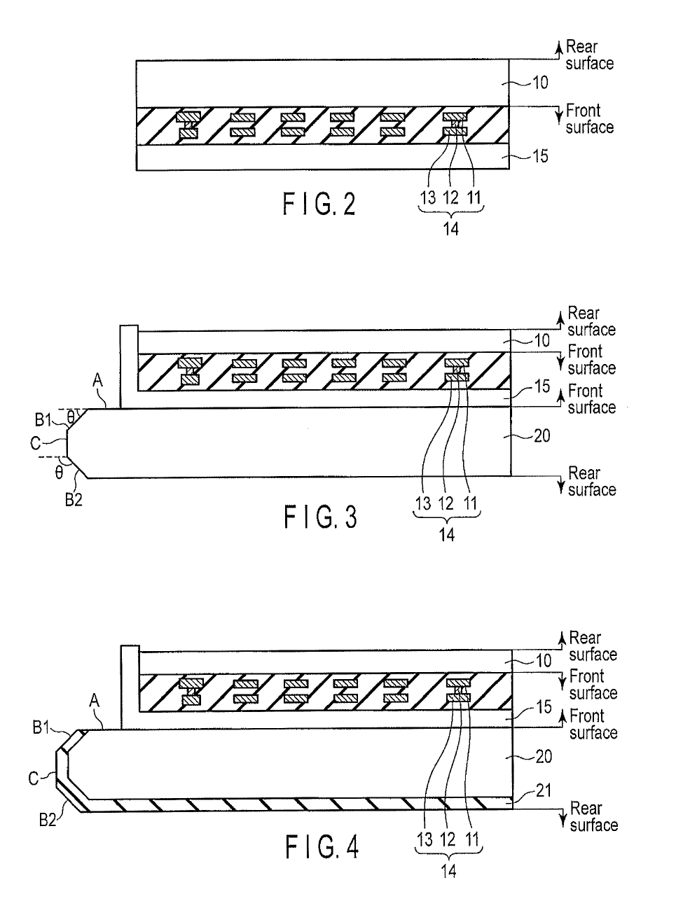

Next, a preliminary process (steps S1 to S6 in FIG. 1) of TSV formation in the semiconductor device according to this embodiment will be described below by using FIGS. 2, 3, 4, 5, 6, 7, 8 and 9.

FIGS. 2, 3, 4, 5 and 6 are cross-sectional views showing the preliminary process of TSV formation in the semiconductor device according to this embodiment.

First, as shown in FIG. 2, on the front surface of the semiconductor substrate 10 constituted of, for example, a Si substrate, circuits 14 are formed. The circuit 14 is constituted of, for example, wiring layers 11 and 13, and a via 12 connecting these layers to each other. Thereafter, an adhesive 15 is applied to the front surface side of the semiconductor substrate 10. The adhesive 15 is constituted of a composite material containing, for example, an acrylic resin, and the like. However, the adhesive 15 is not limited to the above, and it is desirable that the adhesive 15 be constituted of a material which has relatively high repellency to a silane coupling agent to be described later, and prevents the silane coupling agent from flowing to the rear surface side of the semiconductor substrate 10 in the water-repellent treatment process.

Next, as shown in FIG. 3, the front surface of the semiconductor substrate 10, and front surface of the support substrate 20 are bonded to each other through the adhesive 15. Thereby, the semiconductor substrate 10 is supported on the support substrate 20. Although the support substrate 20 is constituted of, for example, a glass substrate, the support substrate is not limited to this, and may be constituted of a Si substrate.

Further, the support substrate 20 has, at the circumferential part thereof, an edge part A, bevel parts B1 and B2, and side part C.

Here, the edge part A is part of the front surface of the support substrate 20, and indicates the surface to be exposed when the semiconductor substrate 10 is bonded to the support substrate 20. This edge part A is not exposed in some cases depending on the bonding state between the support substrate 20 and semiconductor substrate 10.

The bevel part B1 is an end edge corner part on the front surface side of the support substrate 20 adjacent to the edge part A, and indicates a surface having inclination with respect to the film surface (front surface and rear surface) of the support substrate 20. It should be noted that, here, the expression “having inclination with respect to the film surface” implies that the angle θ between the bevel part B1 and the film surface is within a range of 0°<0<90°.

The bevel part B2 is an end edge corner part on the rear surface side of the support substrate 20, and indicates a surface having inclination with respect to the film surface of the support substrate 20. It should be noted that, here, the expression “having inclination with respect to the film surface” implies that the angle θ between the bevel part B2 and the film surface is within a range of 90°<θ<180°.

The side part C is positioned between the bevel part B1 and bevel part B2, and indicates the side surface of the support substrate 20. Although the side part C forms an angle of 90° with the film surface of the support substrate 20, the angle is not limited to this.

It should be noted that the support substrate 20 may have curvatures at the bevel parts B1 and B2, and side part C. That is, each of the bevel parts B1 and B2, and side part C may be formed in such a manner that an angle between a tangential line thereof and the film surface continuously changes from 0° to 180° from the front surface side toward the rear surface side.

Further, in the following description, there are cases where each of the bevel parts B1 and B2, and side part C do not indicate a surface of the support substrate 20, but indicate a surface of a protective film 21 to be described later.

Next, as shown in FIG. 4, a protective film 21 is formed on the support substrate 20 by, for example, plasma chemical vapor deposition (CVD). More specifically, the protective film 21 is formed on the surfaces of the support substrate 20 other than the bonding plane between the support substrate 20 and adhesive 15.

At this time, the plasma CVD is carried out from the rear surface side of the support substrate 20. Accordingly, the protective film 20 is formed on the rear surface, bevel part B2, and side part C of the support substrate 20. However, it is hard for the protective film 21 to be formed on the bevel part B1 and edge part A. Accordingly, on the bevel part B1 and edge part A, a protective film 21 thinner than the rear surface, bevel part B2, and side part C is formed. Further, on the edge part A, a protective film 21 thinner than the bevel part B1 is formed.

It should be noted that no protective film 21 is formed on the bevel part B1, and edge part A in some cases. In such a case, the support substrate 20 is left exposed at the bevel part B1 and edge part A.

Although the protective film 21 is constituted of, for example, an SiN film, the protective film 21 is not limited to this, and may be constituted of an SiO₂ film. Further, the protective film 21 may be a laminated film formed by laminating an SiO₂ film, and SiN film in the order mentioned from the support substrate 20 side. From a viewpoint of resistance to wet etching to be described later, it is desirable that the protective film 21 be constituted of an SiN film.

It should be noted that when there is no possibility of the support substrate 20 itself being contaminated or being changed in shape in the subsequent or later process, the protective film 21 may not be formed.

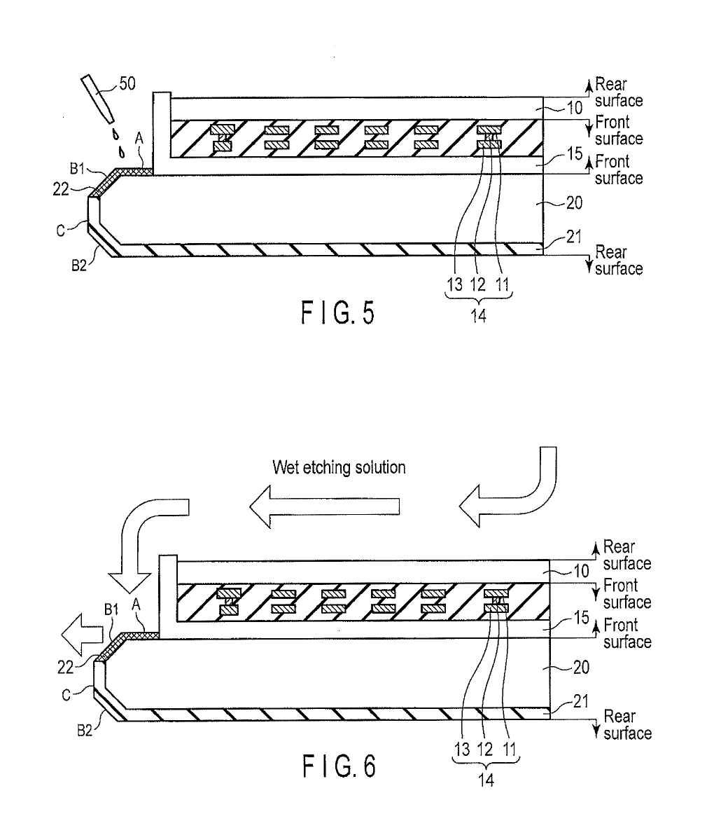

Next, after the semiconductor substrate 10, and support substrate 20 are introduced into a wet treatment chamber, the circumferential part of the support substrate 20 is subjected to water-repellent treatment as shown in FIG. 5. Thereby, a water-repellent area 22 is formed on the circumferential part of the support substrate 20 in such a manner that the area 22 is in contact with the end face of the adhesive 15. Details of the method of forming the water-repellent area 22 will be described later.

Next, as shown in FIG. 6, the semiconductor substrate 10 is subjected to thinning from the rear surface side thereof by spin-system wet etching.

More specifically, an etching solution such as hydrofluoric acid/nitric acid or the like is discharged from a nozzle (not shown) onto a central part on the rear surface side of the semiconductor substrate 10 while the semiconductor substrate 10, and support substrate 20 are being rotated. The etching solution flows from the central part toward the outer circumferential part by the centrifugal force resulting from the rotation of the semiconductor substrate 10, and support substrate 20 to thereby etch the rear surface of the semiconductor substrate 10. Thereafter, the etching solution is discharged to the outside of the semiconductor substrate 10 by the centrifugal force resulting from the high-speed rotation.

At this time, the etching solution discharged to the outside of the semiconductor substrate 10 flows to the circumferential part of the support substrate 20. In this embodiment, the circumferential part of the support substrate 20 has been subjected to the water-repellent treatment. Accordingly, the etching solution is discharged to the outside to be collected without advancing to the rear surface side of the support substrate 20.

The rotational speed of the semiconductor substrate 10, and support substrate 20 in the wet etching process is 300 rpm or more, and 1000 rpm or less. By making the rotational speed 300 rpm or more, it is possible to sufficiently prevent the etching solution from advancing to the rear surface side of the support substrate 20. Further, by making the rotational speed 1000 rpm or less, it is possible to prevent the etching characteristics of the semiconductor substrate 10 from being deteriorated.

Thereafter, pure water rinsing is carried out in order to remove the residual etching solution. Furthermore, spin drying is carried out, and the semiconductor substrate 10, and support substrate 20 are transferred from the wet treatment chamber. In this way, the preliminary process of the TSV in this embodiment is carried out.

Hereinafter, the method of forming the water-repellent area 22 in this embodiment will be described in detail.

First, after the semiconductor substrate 10 and support substrate 20 are introduced into the wet treatment chamber, the semiconductor substrate 10 and support substrate 20 are rotated. The rotational speed is, for example, several hundred rpm. By the centrifugal force resulting from the rotational speed, it is possible to prevent the rear surface of the semiconductor substrate 10 from being subjected to the water-repellent treatment.

Next, a dedicated treatment nozzle 50 is made close to the circumferential part of the support substrate 20. As the dedicated treatment nozzle 50, for example, a tube type nozzle is used, and is adjusted in such a manner that discharge is carried out aiming at the circumferential part.

Further, a silane coupling agent is discharged from the dedicated treatment nozzle 50. A silylation reaction is caused at the circumferential part of the support substrate 20 by the silane coupling agent, and a water-repellent area 22 is formed.

The silane coupling agent includes, in the molecule, a hydrolyzable group having affinity with and reactivity to an inorganic material, and organofunctional group chemically combining with an organic material, and is, for example, hexamethyldisilazane (HMDS), tetramethylsilyldiethylamine (TMSDEA) or the like. A trimethylsilane group is formed by the dehydration reaction of the silane coupling agent, whereby the water-repellant area 22 is formed. Accordingly, the reaction may be promoted by carrying out annealing treatment to thereby raise the liquid temperature or by carrying out ultraviolet irradiation.

At this time, when the constituent material of the outermost surface (support substrate 20 or protective film 21) of the circumferential part has no hydroxyl group, the silylation reaction becomes insufficient.

More specifically, when the outermost surface is the support substrate 20 constituted of a Si substrate or the protective film 21 constituted of an SiN film, the silylation reaction hardly occurs. In such cases, the outermost surface of the circumferential part is oxidized by using, for example, wet ozone or the like as a preliminary process of the water-repellent treatment. Thereby, it is possible to form hydroxyl groups in the outermost surface of the circumferential part.

It should be noted that when the outermost surface is the support substrate 20 constituted of a glass substrate or the protective film 21 constituted of an SiO₂ film, sufficient hydroxyl groups exist in the outermost surface, and hence the above-mentioned oxidization process is not necessary. Further, when the outermost surface is the support substrate 20 constituted of a Si substrate, if a natural oxide film is formed on the outermost surface, sufficient hydroxyl groups exist in the outermost surface, and hence the above oxidation process is not necessary.

Further, when the protective film 21 constituted of an SiN film is formed on the support substrate 20 constituted of a glass substrate, the SiN film of the circumferential part may be removed by using hydrofluoric acid or the like in place of carrying out the above-mentioned oxidation process to thereby expose the glass substrate and make the glass substrate the outermost surface.

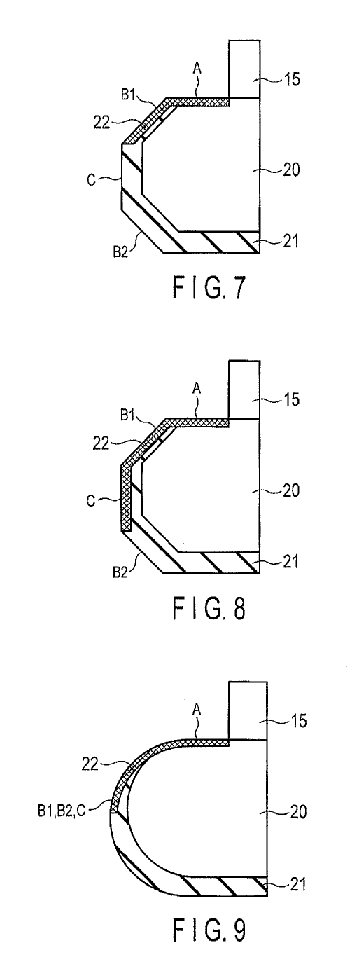

FIGS. 7, 8 and 9 are enlarged views showing examples of the water-repellent area 22 in FIG. 5.

As shown in FIG. 7, the water-repellent area 22 is formed on the edge part A, and bevel part B1 of the support substrate 20 (and/or protective film 21). Further, the water-repellent area 22 is formed in such a manner that the area 22 is in contact with at least the end face of the adhesive 15 at the edge part A. In other words, the water-repellent area 22 is formed to be continuous from the end face of the adhesive 15 at the edge part A. That is, the front surface of the support substrate 20 is covered with the adhesive 15, and water-repellent area 22. Thereby, it is possible to prevent the front surface side of the support substrate 20 from being etched by the etching solution, and sufficiently prevent the etching solution from advancing toward the rear surface side of the support substrate 20.

It should be noted that as shown in FIG. 8, it is desirable that the water-repellent area 22 be formed also on the side part C of the support substrate 20 (and/or protective film 21). Thereby, it is possible to further prevent the etching solution from advancing toward the rear surface side of the support substrate 20.

Further, as shown in FIG. 9, when each of the bevel parts B1 and B2, and side part C of the support substrate 20 (and/or protective film 21) has a curvature, the water-repellent area 22 is formed from a position at which the edge part A is in contact with the adhesive 15 to a position at which an angle formed by a tangential line of each of the bevel parts B1 and B2, and side part C with the film surface becomes 90°. Thereby, even when each of the bevel parts B1 and B2, and side part C has a curvature, it is possible to sufficiently prevent the etching solution from advancing toward the rear surface side of the support substrate 20.

It should be noted that formation of the water-repellent area 22 is not limited to the edge part A, bevel part B1, and side part C, and the water-repellent area 22 may be formed on the bevel part B2, and the rear surface side.

After the water-repellent area 22 is formed, alcohol rinsing and pure water rinsing are carried out in order to remove the residual silane coupling agent. Furthermore, spin drying is carried out to dry out the circumferential part. In this way, the water-repellent treatment in this embodiment is carried out.

It should be noted that it is possible to easily remove the water-repellent area 22 by carrying out the RIE in the TSV formation process in step S7 shown in FIG. 1, and the oxidation treatment such as ashing treatment to be carried out thereafter, and by separately carrying out additional treatment such as ultraviolet (UV) irradiation or the like. Alternatively, in the regeneration treatment process of the support substrate 20 to be carried out after the separation process of step S9 shown in FIG. 1, too, it is possible to easily remove the water-repellent area 22 by carrying out the oxidation treatment and UV irradiation treatment or the like.

### [Advantage]

According to the above-mentioned embodiment, the circumferential part of the support substrate 20 (and/or protective film 21) supporting the semiconductor substrate 10 is subjected to the water-repellent treatment as a preliminary process of the film-thinning process of the semiconductor substrate 10 to be carried out by the spin-system wet etching.

Thereby, it is possible to prevent the support substrate 20 from being etched by the etching solution. That is, it is possible to prevent damage to the support substrate 20 such as a change in shape of the support substrate 20 from occurring. As a result, it is possible to increase the number of times of repetitive use of the support substrate 20.

Further, when a protective film 21 is formed on the support substrate 20, it is possible to prevent the protective film 21 from being etched to expose the support substrate 20. Thereby, it becomes possible to prevent any metal in the impurities contained in the support substrate 20 from diffusing in the subsequent or later thermal process or the like. Thereby, it is possible to reduce the contamination risk originating from the support substrate 20 such as contamination of the semiconductor substrate 10, and secondary contamination of another semiconductor substrate to be subsequently processed.

Further, by rotating the semiconductor substrate 10, and support substrate 20 at a relatively low rotational speed, it is possible to discharge and collect the etching solution. That is, it becomes unnecessary to carry out etching at a high rotational speed, and it is possible to prevent the etching characteristics of the semiconductor substrate 10 from being deteriorated by the high-speed rotation.

Furthermore, the processes from the water-repellent treatment process of the support substrate 20 to the wet etching process of the semiconductor substrate 10 are carried out in the same wet treatment chamber. Transfer between chambers is not carried out, and hence, even when the water-repellent treatment process of the support substrate 20 in this embodiment is carried out, it is possible to hold down an increase in treating time to the minimum necessary degree.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
bonding a front surface of a semiconductor substrate and a front surface of a support substrate to each other by an adhesive;
subjecting a part of a circumferential part of the support substrate to water-repellent treatment to thereby form a water-repellent area on the part of the circumferential part in such a manner that the water-repellent area and an end face of the adhesive are in contact with each other; and
removing the semiconductor substrate from a rear surface side by wet etching.

2. The method of claim 1, further comprising forming a protective film on the support substrate after bonding the semiconductor substrate and the support substrate to each other.

3. The method of claim 2, wherein the support substrate includes a glass substrate, and the protective film includes an SiN film, an SiO₂ film or a laminated film formed by laminating an SiO₂ film and an SiN film in the order mentioned from the support substrate side.

4. The method of claim 1, wherein the water-repellent treatment is carried out by using a silane coupling agent.

5. The method of claim 2, further comprising oxidizing the protective film before forming the water-repellent area.

6. The method of claim 1, wherein the adhesive has repellency to the silane coupling agent.

7. The method of claim 6, wherein the adhesive includes a composite material containing an acrylic resin.

8. The method of claim 1, wherein the wet etching is wet etching of the spin system, and the rotational speed of the semiconductor substrate and the support substrate in the spin-system wet etching is 300 rpm or more, and 1000 rpm or less.

9. The method of claim 4, wherein the silane coupling agent is HMDS or TMSDEA.

10. The method of claim 4, wherein in the water-repellent treatment, annealing treatment and/or ultraviolet irradiation are carried out.

11. The method of claim 4, wherein hydroxyl groups exist in the outermost surface of the part of the circumferential part.

12. The method of claim 1, wherein the part of the circumferential part is an edge part, and a bevel part adjacent to the edge part.

13. The method of claim 1, further comprising removing the water-repellent area after removing the semiconductor substrate from the rear surface side.

14. The method of claim 13, wherein the removal of the water-repellent area is carried out by ashing treatment and UV irradiation treatment.

15. A method of manufacturing a semiconductor device comprising:
bonding a front surface of a semiconductor substrate and a front surface of a support substrate constituted of a glass substrate to each other through an adhesive;
forming a protective film including an SiN film, an SiO₂ film or a laminated film formed by laminating an SiO₂ film, and an SiN film in the order mentioned from the support substrate side on the support substrate;
oxidizing the protective film;
subjecting a part of a circumferential part of the support substrate and/or the protective film to water-repellent treatment by using a silane coupling agent to thereby form a water-repellent area on the part of the circumferential part in such a manner that the water-repellent area and an end face of the adhesive are in contact with each other; and
removing the semiconductor substrate from a rear surface side by wet etching.

16. The method of claim 15, wherein the adhesive has repellency to the silane coupling agent.

17. The method of claim 16, wherein the adhesive includes a composite material containing an acrylic resin.

18. The method of claim 15, wherein the wet etching is wet etching of the spin system, and the rotational speed of the semiconductor substrate and the support substrate in the spin-system wet etching is 300 rpm or more, and 1000 rpm or less.

19. The method of claim 15, further comprising removing the water-repellent area after removing the semiconductor substrate from the rear surface side.

20. The method of claim 19, wherein the removal of the water-repellent area is carried out by ashing treatment and UV irradiation treatment.
